(19) United States
(12) Patent Application Publication
(10) Pub. No.: US 2008/0271908 A1
(43) Pub. Date: Nov. 6, 2008

(54) Hermetic Sealing Cap, Method of Manufacturing Hermetic Sealing Cap and Electronic Component Storage Package

(75) Inventors: Masaharu Yamamoto, Kagoshima (JP); Kenji Takano, Kagoshima (JP); Junji Hira, Kagoshima (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: NEOMAX MATERIALS CO., LTD., Suita-shi (JP)

(21) Appl. No.: 10/568,075

(22) PCT Filed: Sep. 26, 2005
(86) PCT No.: PCT/JP05/17599

§ 371 Date: Feb. 13, 2006

(30) Foreign Application Priority Data
Nov. 5, 2004 (JP) 2004-321631

(51) Int. Cl. H05K 5/06; B05D 5/12

(52) U.S. Cl. 174/50.5; 174/66; 427/125

(57) ABSTRACT

Cap for airtight sealing (1) that not only suppresses any deterioration of the properties of electronic parts (20) to thereby reduce material costs but also enables use of Pb-free solders, and that is capable of suppressing any airtightness deterioration. This cap for airtight sealing comprises low thermal expansion layer (2); Ni—Co alloy layer (3) superimposed on the surface of the low thermal expansion layer and composed mainly of Ni wherein a diffusion acceleration material is contained; Ni layer (4) superimposed on the surface of the Ni—Co alloy layer; and solder layer (5) superimposed on the surface of the Ni layer at regions for bonding of electronic part accommodation member (10) and composed mainly of Sn. The Ni layer has the functions of not only suppressing any diffusion of the Ni—Co alloy layer into the solder layer at about 235° C. (first temperature) but also at bonding of the solder layer with the electronic part accommodation member at about 300° to about 320° C. (second temperature), diffusing the Ni—Co alloy layer via the Ni layer into the solder layer.

### TECHNICAL FIELD

The present invention relates to a hermetic sealing cap, a method of manufacturing a hermetic sealing cap and an electronic component storage package, and more particularly, it relates to a hermetic sealing cap employed for storing an electronic component, a method of manufacturing a hermetic sealing cap and an electronic component storage package.

### BACKGROUND ART

An electronic component storage package such as an SMD (Surface Mount Device) package (surface mount device package) employed for hermetically sealing an electronic component such as a SAW filter (surface acoustic wave filter) or a crystal oscillator employed for noise removal of a portable telephone or the like is known in general. Such an electronic component storage is constituted of an electronic component storing member (case) on which the electronic component is mounted and a hermetic sealing cap hermetically sealing the electronic component storing member. This hermetic sealing cap is heated to be bonded to the electronic component storing member through a solder layer. Thereafter the electronic component package is reheated to be mounted on a printed wiring board of an electronic apparatus or the like. In general, high melting point solder mainly composed of noble metal such as an Au—Sn alloy (Sn: about 20 mass %) or high-melting point consisting of an Sn—Pb alloy is employed so that a sealed portion of the hermetic sealing cap is not melted when the electronic component storage package is mounted on the printed wiring board of the electronic apparatus or the like. However, since the high melting point solder consisting of the Au—Sn alloy is remarkably high-priced and the high melting point solder consisting of the Sn—Pb alloy contains Pb, it is preferable not to use the same in view of environment or the like.

In general, therefore, there is proposed an electronic component storage package rendering a sealed portion of a hermetic sealing cap unmelted when the electronic component storage package is mounted on a printed wiring board of an electronic apparatus or the like also in a case of employing low melting point solder for the sealed portion of the hermetic sealing cap. Such an electronic component storage package is disclosed in International Laying-Open Gazette No. WO02/078085, for example. In the aforementioned International Laying-Open Gazette No. WO02/078085, there is disclosed an electronic component package employing a lid body (hermetic sealing cap) integrally formed by arranging an Ni group metal layer on the upper surface of a core portion (substrate) while superposing an Ni alloy layer diffusing into a brazing filler metal layer in hermetic sealing and the brazing filler metal layer (solder layer) on the lower surface in this order and thereafter pressure-welding/bonding these four layer members to each other. In such an electronic component package, the Ni alloy layer diffuses into the brazing filler metal layer in hermetic sealing, whereby an intermetallic compound is formed in the brazing filler metal layer. Thus, the melting point of the solder layer can be increased, whereby a sealed portion of the lid body can be inhibited from melting when the electronic component package is mounted on a printed wiring board of an electronic apparatus or the like. In the structure disclosed in the aforementioned International Laying-Open Gazette No. WO02/078085, however, the lid body is integrally formed by pressure-welding/bonding the four layer members including the brazing filler metal layer to each other, whereby the brazing filler metal layer is arranged to cover the upper surface of an electronic component arranged in the electronic component package. Thus, there is such inconvenience that the brazing filler metal layer may spatter on the electronic component to deteriorate the characteristics of the electronic component when performing hermetic sealing with the lid body.

In order to solve such inconvenience, a countermeasure of forming the Ni alloy layer on the lower surface of the substrate and forming a solder layer only on the sealed portion of the lower surface of the Ni alloy layer in the structure of the aforementioned International Laying-Open Gazette No. WO02/078085. When partially forming the solder layer in this manner, it is general to form the solder layer into which the Ni alloy layer diffuses by arranging solder paste on the sealed portion of the lower surface of the Ni alloy layer and thereafter melting the solder paste.

When the solder layer is formed by arranging the solder paste on the sealed portion of the lower surface of the Ni alloy layer and thereafter melting the solder paste in the structure of the aforementioned International Laying-Open Gazette No. WO02/078085, however, such inconvenience takes place that an intermetallic compound is formed in the solder layer and the melting point of the solder layer increases when forming the solder layer by melting the solder paste. Thus, there is such inconvenience that the solder layer is hard to melt when bonding the hermetic sealing cap to an electronic component storing member by melting the solder layer after formation of the solder layer. Consequently, there is such a problem that wettability of the solder layer with respect to the electronic component storing member so lowers that airtightness of the electronic component storing package may lower.

### DISCLOSURE OF THE INVENTION

The present invention has been proposed in order to solve the aforementioned problems, and an object of the present invention is to provide a hermetic sealing cap capable of suppressing deterioration of the characteristics of an electronic component, reducing the material cost, using solder containing no Pb and suppressing lowering of airtightness, a method of manufacturing a hermetic sealing cap, an electronic component storage package and a method of manufacturing an electronic component storage package.

In order to attain the aforementioned object, a hermetic sealing cap according to a first aspect of the present invention, which is a hermetic sealing cap employed for an electronic component storage package including an electronic component storing member for storing an electronic component, comprises a substrate, a first layer, formed on the surface of the substrate, mainly composed of Ni containing a diffusion accelerator, a second layer formed on the surface of the first layer and a solder layer mainly composed of Sn formed on a region of the surface of the second layer to which the electronic component storing member is bonded, and the second layer has a function of inhibiting the first layer from diffusing into the solder layer at a first temperature while diffusing the first layer into the solder layer through the second layer when the solder layer bonds to the electronic component storing member at a second temperature higher than the first temperature.

In the hermetic sealing cap according to the first aspect of the present invention, as hereinabove described, it is possible to suppress formation of an intermetallic compound in the solder layer at the first temperature by making the second layer function to inhibit the first layer from diffusing into the solder layer at the first temperature, whereby it is possible to inhibit the melting point of the solder layer from increasing. Thus, wettability of the solder layer with respect to the electronic component storing member can be inhibited from lowering when bonding the hermetic sealing cap to the electronic component storing member through the solder layer by heating the same to the second temperature higher than the first temperature, whereby airtightness of the electronic component storage package can be inhibited from lowering. Further, the solder layer can be inhibited from covering the upper surface of the electronic component arranged in the electronic component storage package by forming the solder layer mainly composed of Sn on the region of the surface of the second layer to which the electronic component storing member is bonded, whereby the solder layer can be inhibited from spattering on the electronic component when bonding the hermetic sealing cap to the electronic component storing member. Thus, deterioration of the characteristics of the electronic component can be suppressed. Further, the intermetallic compound can be formed in the solder layer by making the second layer function to diffuse the first layer into the solder layer through the second layer when the solder layer bonds to the electronic component storing member at the second temperature higher than the first temperature, whereby the melting point of the solder can be increased. Thus, the solder layer can be inhibited from melting resulting from such a situation that the electronic component storage package reaches a high temperature while the solder layer also reaches a high temperature when mounting the electronic component storage package on a printed wiring board of an electronic apparatus. In this case, there is no need to employ high melting point solder consisting of a high-priced Au—Sn alloy or an Sn—Pb alloy, whereby the material cost can be reduced and solder containing no Pb can be used.

In the aforementioned hermetic sealing cap according to the first aspect, the first temperature is preferably a temperature at a time of forming the solder layer by melting solder paste, and the second temperature is preferably a temperature at a time of bonding the hermetic sealing cap to the electronic component storing member by melting the solder layer. According to this structure, formation of an intermetallic compound in the solder layer can be suppressed due to the function of the second layer at the first temperature for forming the solder layer by melting the solder paste, whereby the melting point of the solder layer can be easily inhibited from increasing in formation of the solder layer. Thus, the solder layer is easily meltable when bonding the hermetic sealing cap to the electronic component storing member, whereby the hermetic sealing cap can be easily bonded to the electronic component storing member.

In the aforementioned hermetic sealing cap according to the first aspect, the second layer is preferably made of Ni. According to this structure, the first layer can be easily inhibited from diffusing into the solder layer through the second layer consisting of Ni.

In the aforementioned hermetic sealing cap having the second layer made of Ni, the second layer preferably has a thickness of at least 0.03 μm and not more than 0.075 μm. According to this structure, the second layer consisting of Ni can be easily formed to have the function of inhibiting the first layer from diffusing into the solder layer at the first temperature while diffusing the first layer into the solder layer through the second layer when the solder layer bonds to the electronic component storing member at the second temperature higher than the first temperature.

In the aforementioned hermetic sealing cap according to the first aspect, the first layer preferably contains 7.5 mass % to 20 mass % of Co as the diffusion accelerator. According to this structure, the first layer can be sufficiently diffused into the solder layer through the second layer when the solder layer is bonded to the electronic component storing member at the second temperature higher than the first temperature, whereby a sufficient quantity of intermetallic compound can be formed in the solder layer.

In the aforementioned hermetic sealing cap according to the first aspect, the substrate is preferably made of an Fe—Ni—Co alloy. According to this structure, the thermal expansion coefficient of the substrate can be so reduced that the thermal expansion coefficient of the hermetic sealing cap can be reduced. Thus, thermal expansion coefficient difference between the hermetic sealing cap and the electronic component storing member can be reduced when the electronic component storing member is made of a material such as ceramic having a small thermal expansion coefficient, whereby the junction between the hermetic sealing cap and the electronic component storing member can be inhibited from development of cracks and chaps under a high temperature.

In the aforementioned hermetic sealing cap according to the first aspect, the first layer and the second layer are preferably formed by plating. According to this structure, the first layer and the second layer can be easily formed.

In the aforementioned hermetic sealing cap having the first layer and the second layer formed by plating, the first layer is preferably formed on the whole area of the surface of the substrate, and the second layer is preferably formed on the whole area of the surface of the first layer. According to this structure, the first layer and the second layer can be easily formed by plating.

In the aforementioned hermetic sealing cap according to the first aspect, the solder layer preferably contains no Pb, and contains Ag. Also when employing low melting point solder consisting of Sn—Ag containing no Pb in this manner, an intermetallic compound increasing the melting point of the solder layer is formed in bonding between the hermetic sealing cap and the electronic component storing member due to the aforementioned structure of the present invention, whereby the solder layer can be inhibited from melting when mounting the electronic component storage package on a printed wiring board of an electronic apparatus or the like.

An electronic component storage package according to a second aspect of the present invention, which is an electronic component storage package including an electronic component storing member for storing an electronic component, comprises a hermetic sealing cap including a substrate, a first layer, formed on the surface of the substrate, mainly composed of Ni containing a diffusion accelerator, a second layer formed on the surface of the first layer and a solder layer mainly composed of Sn formed on a region of the surface of the second layer to which the electronic component storing member is bonded with the second layer having a function of inhibiting the first layer from diffusing into the solder layer at a first temperature while diffusing the first layer into the solder layer through the second layer when the solder layer bonds to the electronic component storing member at a second temperature higher than the first temperature, a third layer is formed on a portion of the electronic component storing member corresponding to the solder layer, the solder layer and the third layer are bonded to each other, and an intermetallic compound containing Sn of the solder layer is formed on the junction between the hermetic sealing cap and the electronic component storing member.

In the electronic component storage package according to the second aspect of the present invention, as hereinabove described, formation of an intermetallic compound in the solder layer can be suppressed at the first temperature by making the second layer function to inhibit the first layer from diffusing into the solder layer at the first temperature, whereby the melting point of the solder layer can be inhibited from increasing. Thus, wettability of the solder layer with respect to the electronic component storing member can be inhibited from lowering when bonding the hermetic sealing cap to the electronic component storing member through the solder layer by heating the same to the second temperature higher than the first temperature, whereby airtightness of the electronic component storage package can be inhibited from lowering. Further, the solder layer mainly composed of Sn is so formed on the region of the surface of the second layer to which the electronic component storing member is boned that the solder layer can be inhibited from covering the upper surface of the electronic component arranged in the electronic component storage package, whereby the solder layer can be inhibited from spattering on the electronic component when bonding the hermetic sealing cap to the electronic component storing member. Thus, deterioration of the characteristics of the electronic component can be suppressed. Further, an intermetallic compound can be formed in the solder layer by making the second layer function to diffuse the first layer into the solder layer through the second layer when the solder layer bonds to the electronic component storing member at the second temperature higher than the first temperature, whereby the melting point of the solder layer can be increased. Thus, the solder layer can be inhibited from melting resulting from such a situation that the electronic component storage package reaches a high temperature while the solder layer also reaches a high temperature when mounting the electronic component storage package on a printed wiring board of an electronic apparatus. In this case, there is no need to employ high melting point solder consisting of a high-priced Au—Sn alloy or an Sn—Pb alloy, whereby the material cost can be reduced and solder containing no Pb can be used.

In the aforementioned electronic component storage package according to the second aspect, the junction between the hermetic sealing cap and the electronic component storing member preferably contains an intermetallic compound consisting of an Ni—Sn alloy, and a portion of the second layer corresponding to the junction between the hermetic sealing cap and the electronic component storing member preferably diffuses in the intermetallic compound. According to this structure, the first layer can be easily diffused into the solder layer through the second layer.

A method of manufacturing a hermetic sealing cap according to a third aspect of the present invention, which is a method of manufacturing a hermetic sealing cap employed for an electronic component storage package including an electronic component storing member for storing an electronic component, comprises steps of preparing a substrate, forming a first layer mainly composed of Ni containing a diffusion accelerator on the surface of the substrate, forming a second layer on the surface of the first layer and forming a solder layer mainly composed of Sn on a region of the surface of the second layer to which the electronic component storing member is bonded, and the step of forming the second layer includes a step of forming the second layer having a function of inhibiting the first layer from diffusing into the solder layer when forming the solder layer at a first temperature while diffusing the first layer into the solder layer through the second layer when the solder layer bonds to the electronic component storing member at a second temperature higher than the first temperature.

In the method of manufacturing a hermetic sealing cap according to the third aspect of the present invention, as hereinabove described, the step of forming the second layer includes the step of forming the second layer having the function of inhibiting the first layer from diffusing into the solder layer when forming the solder layer at the first temperature so that formation of an intermetallic compound in the solder layer can be suppressed at the first temperature, whereby the melting point of the solder layer can be inhibited from increasing. Thus, wettability of the solder layer with respect to the electronic component storing member can be inhibited from lowering when bonding the hermetic sealing cap to the electronic component storing member through the solder layer by heating the same to the second temperature higher than the first temperature, whereby airtightness of the electronic component storage package can be inhibited from lowering. Further, the solder layer mainly composed of Sn is so formed on the region of the surface of the second layer to which the electronic component storing member is bonded that the solder layer can be inhibited from covering the upper surface of the electronic component arranged in the electronic component storage package, whereby the solder layer can be inhibited from spattering on the electronic component when bonding the hermetic sealing cap to the electronic component storing member. Thus, deterioration of the characteristics of the electronic component can be suppressed. Further, an intermetallic compound can be formed in the solder layer by making the second layer function to diffuse the first layer into the solder layer through the second layer when the solder layer bonds to the electronic component storing member at the second temperature higher than the first temperature, whereby the melting point of the solder layer can be increased. Thus, the solder layer can be inhibited from melting resulting from such a situation that the electronic component storage package reaches a high temperature while the solder layer also reaches a high temperature when mounting the electronic component storage package on a printed wiring board of an electronic apparatus. In this case, there is no need to employ solder consisting of a high-priced Au—Sn alloy or an Sn—Pb alloy, whereby the material cost can be reduced and solder containing no Pb can be used.

In the aforementioned method of manufacturing a hermetic sealing cap according to the third aspect, the step of forming the solder layer preferably includes steps of arranging solder paste mainly composed of Sn on a region of the surface of the second layer to which the electronic component storing member is bonded and forming the solder layer mainly composed of Sn by melting the solder paste at the first temperature. According to this structure, the solder layer mainly composed of Sn can be easily formed only on the region of the surface of the second layer to which the electronic component storing member is bonded.

In the aforementioned method of manufacturing a hermetic sealing cap according to the third aspect, the second layer is preferably made of Ni. According to this structure, the first layer can be easily inhibited from diffusing into the solder layer through the second layer consisting of Ni.

In the aforementioned method of manufacturing a hermetic sealing cap having the second layer made of Ni, the second layer preferably has a thickness of at least 0.03 μm and not more than 0.075 μm. According to this structure, the second layer consisting of Ni can be easily formed to have the function of inhibiting the first layer from diffusing into the solder layer at the first temperature while diffusing the first layer into the solder layer through the second layer when the solder layer bonds to the electronic component storing member at the second temperature higher than the first temperature.

In the aforementioned method of manufacturing a hermetic sealing cap according to the third aspect, the first layer preferably contains 7.5 mass % to 20 mass % of Co as the diffusion accelerator. According to this structure, the first layer can be sufficiently diffused into the solder layer through the second layer when the solder layer is bonded to the electronic component storing member at the second temperature higher than the first temperature, whereby a sufficient quantity of intermetallic compound can be formed in the solder layer.

In the aforementioned method of manufacturing a hermetic sealing cap according to the third aspect, the substrate is preferably made of an Fe—Ni—Co alloy. According to this structure, the thermal expansion coefficient of the substrate can be reduced, whereby the thermal expansion coefficient of the hermetic sealing cap can be reduced. Thus, thermal expansion coefficient difference between the hermetic sealing cap and the electronic component storing member can be reduced when the electronic component storing member is made of a material such as ceramic having a small thermal expansion coefficient, whereby the junction between the hermetic sealing cap and the electronic component storing member can be inhibited from development of cracks and chaps under a high temperature.

In the aforementioned method of manufacturing a hermetic sealing cap according to the third aspect, the step of forming the first layer preferably includes a step of forming the first layer by plating, and the step of forming the second layer preferably includes a step of forming the second layer by plating. According to this structure, the first layer and the second layer can be easily formed.

In the aforementioned method of manufacturing a hermetic sealing cap having the step of forming the first layer including the step of forming the first layer by plating and the step of forming the second layer including the step of forming the second layer by plating, the step of forming the first layer by plating preferably includes a step of forming the first layer on the whole area of the surface of the substrate, and the step of forming the second layer by plating preferably includes a step of forming the second layer on the whole area of the surface of the first layer. According to this structure, the first layer and the second layer can be more easily formed by plating.

In the aforementioned method of manufacturing a hermetic sealing cap according to the third aspect, the solder layer preferably contains no Pb, and contains Ag. Also when employing low melting point solder consisting of Sn—Ag containing no Pb in this manner, an intermetallic compound increasing the melting point of the solder layer is formed in bonding between the hermetic sealing cap and the electronic component storing member due to the aforementioned structure of the present invention, whereby the solder layer can be inhibited from melting when mounting the electronic component storage package on a printed wiring board of an electronic apparatus or the like.

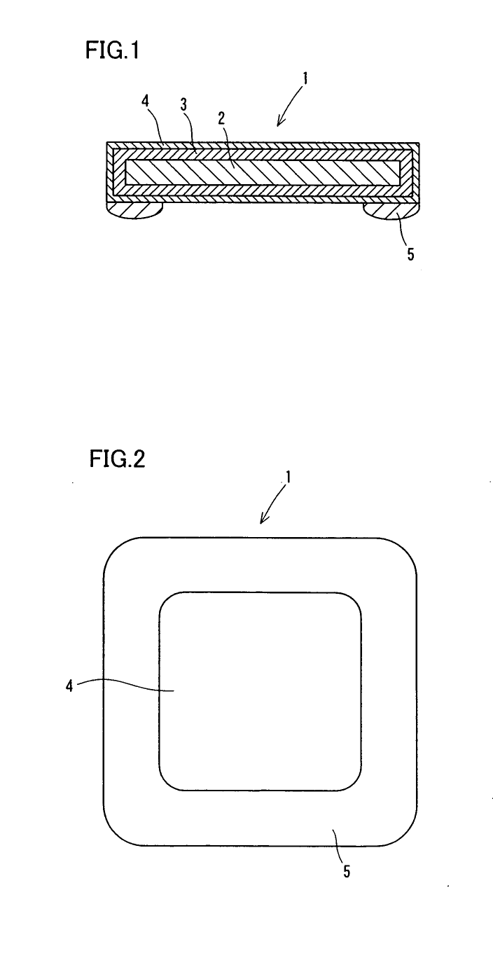

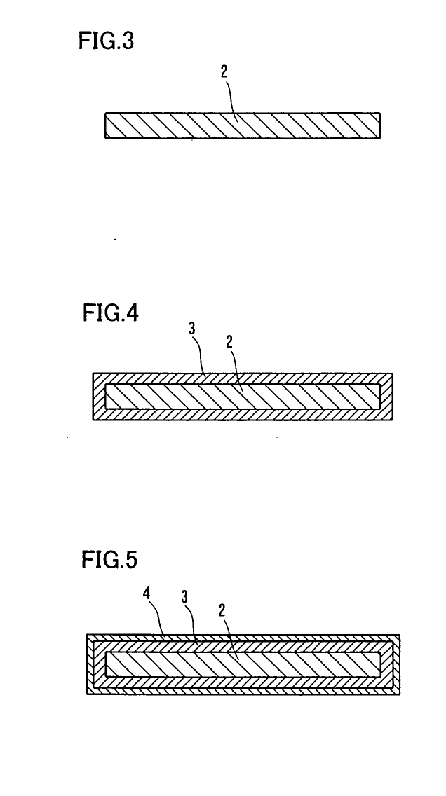

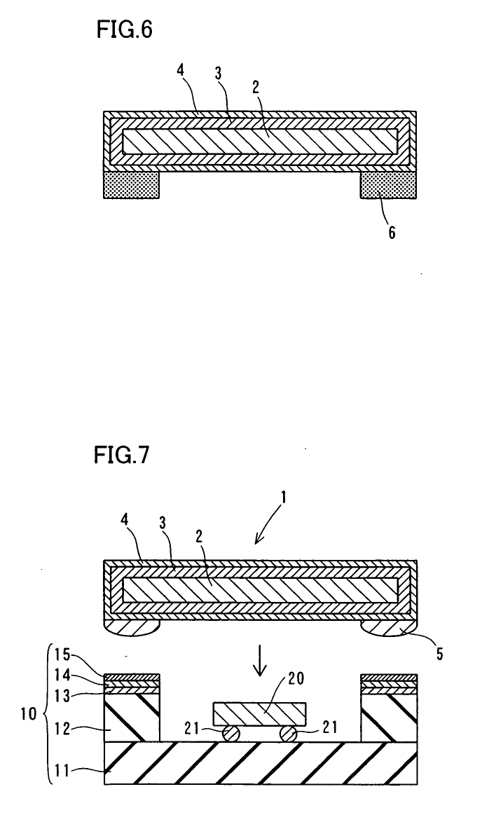

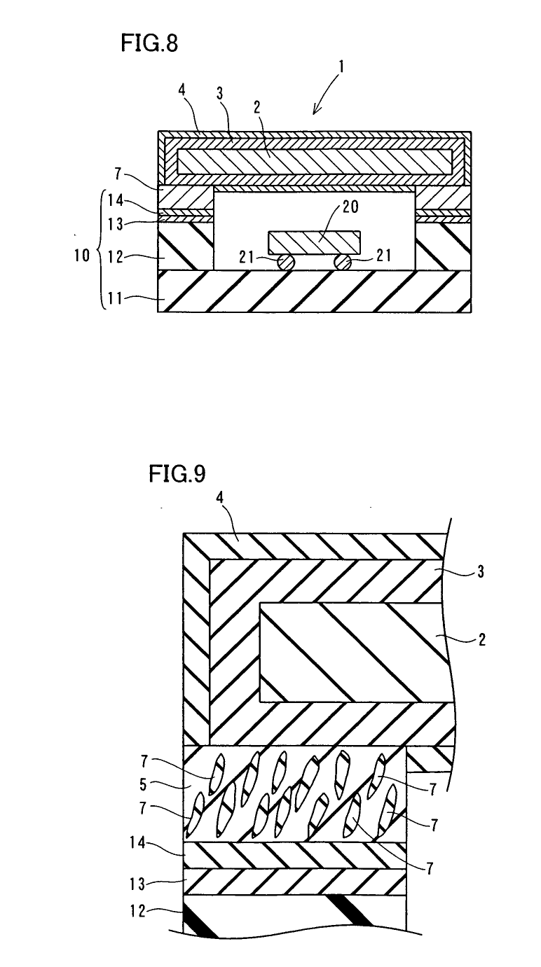

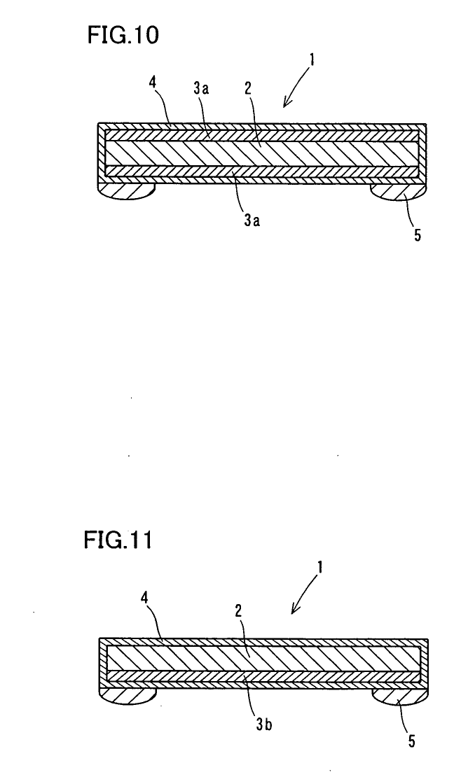

### BRIEF DESCRIPTION OF THE DRAWINGS

[FIG. 1] A sectional view showing a hermetic sealing cap employed for an electronic component storage package according to an embodiment of the present invention.

[FIG. 2] A bottom plan view showing the hermetic sealing cap according to the embodiment of the present invention.

[FIG. 3] A sectional view for illustrating a method of manufacturing the hermetic sealing cap according to the embodiment of the present invention shown in FIG. 1.

[FIG. 4] A sectional view for illustrating the method of manufacturing the hermetic sealing cap according to the embodiment of the present invention shown in FIG. 1.

[FIG. 5] A sectional view for illustrating the method of manufacturing the hermetic sealing cap according to the embodiment of the present invention shown in FIG. 1.

[FIG. 6] A sectional view for illustrating the method of manufacturing the hermetic sealing cap according to the embodiment of the present invention shown in FIG. 1.

[FIG. 7] A sectional view for illustrating a method of manufacturing the electronic component storage package employing the hermetic sealing cap shown in FIG. 1.

[FIG. 8] A sectional view for illustrating the method of manufacturing the electronic component storage package employing the hermetic sealing cap shown in FIG. 1.

[FIG. 9] A sectional view for illustrating the method of manufacturing the electronic component storage package employing the hermetic sealing cap shown in FIG. 1.

[FIG. 10] A sectional view showing a hermetic sealing cap employed for an electronic component storage package according to a first modification of the embodiment of the present invention.

[FIG. 11] A sectional view showing a hermetic sealing cap employed for an electronic component storage package according to a second modification of the embodiment of the present invention.

### BEST MODES FOR CARRYING OUT THE INVENTION

An embodiment of the present invention is now described with reference to the drawings.

First, the structure of a hermetic sealing cap according to the embodiment of the present invention is described with reference to FIGS. 1 and 2.

A hermetic sealing cap 1 according to the embodiment of the present invention includes a low thermal expansion layer 2 consisting of an Fe—Ni—Cu alloy, an Ni—Co alloy (Co: about 7.5 mass % to about 20 mass %) layer 3, containing Co as a diffusion accelerator, formed to enclose the surface of the low thermal expansion layer 2, an Ni layer 4 formed to enclose the surface of the Ni—Co alloy layer 3 and a solder layer 5 consisting of an Sn—Ag alloy (Ag: about 3.5 mass %) formed on a prescribed region of the lower surface of the Ni layer 4. The low thermal expansion layer 2 is an example of the “substrate” in the present invention, and the Ni—Co alloy layer 3 is an example of the “first layer” in the present invention. The Ni layer 4 is an example of the “second layer” in the present invention.

The low thermal expansion layer 2 is about 3.5 mm square, and formed in a thickness of about 0.15 mm. The Ni—Co alloy layer 3 is formed by plating with a thickness of about 2 μm. The Ni layer 4 is formed by plating with a thickness of about 0.03 μm to about 0.075 μm. The solder layer 5 is formed on a region of the lower surface of the Ni layer 4 to which an electronic component storing member 10 described later is bonded, to have a thickness of about 0.05 mm with a width of about 0.45 mm, as shown in FIG. 2.

FIGS. 3 to 6 are sectional views for illustrating a method of manufacturing the hermetic sealing cap according to the embodiment of the present invention shown in FIG. 1. The method of manufacturing the hermetic sealing cap according to the embodiment of the present invention is now described with reference to FIG. 1 and FIGS. 3 to 6.

First, the low thermal expansion layer 2, consisting of the Fe—Ni—Co alloy, of about 3.5 mm square having the thickness of about 0.15 mm is formed by punching a plate coil consisting of an Fe—Ni—Co alloy by press working, as shown in FIG. 3. The Ni—Co alloy layer 3 is formed on the whole areas of the surfaces of this low thermal expansion layer 2 by plating with the thickness of about 2 μm, as shown in FIG. 4. The Ni layer 4 is formed on the whole areas of the surfaces of the Ni—Co alloy layer 3 by plating with the thickness of about 0.03 μm to about 0.075 μm, as shown in FIG. 5.

Then, solder paste 6 is formed on the region of the lower surface of the Ni layer 4 to which the electronic component storing member 10 described later is bonded by screen printing to have a thickness of about 0.08 mm with a width of about 0.45 mm, as shown in FIG. 6. The solder layer 5 is formed to have the thickness of about 0.05 mm by heating the solder paste 6 (see FIG. 6) at a temperature (first temperature) of about 235° C., as shown in FIGS. 1 and 2. Thus, the hermetic sealing cap 1 according to the embodiment of the present invention is formed.

A method of manufacturing an electronic component storage package according to the embodiment of the present invention is now described with reference to FIGS. 7 to 9.

First, the electronic component storing member 10 obtained by forming a tungsten layer 13, an Ni—Co alloy layer 14 and an Au layer 15 on the upper surface of a ceramic frame body 12 arranged on a ceramic substrate 11 in this order is prepared, as shown in FIG. 7. The Ni—Co alloy layer 14 is an example of the “third layer” in the present invention. Thereafter an electronic component 20 having bumps 21 is mounted on the upper surface of the ceramic substrate 11. The solder layer 5 of the hermetic sealing cap 1 formed by the aforementioned method is arranged to be in contact with the upper surface of the ceramic frame body 12. Thereafter the solder layer 5 is melted at a temperature (second temperature) of about 300° C. to about 320° C., thereby bonding the hermetic sealing cap 1 to the upper surface of the ceramic frame body 12. At this temperature (second temperature) of about 300° C. to about 320° C., the Ni layer 4 diffuses into the solder layer 5 consisting of the Sn—Ag alloy, whereby the Ni—Co alloy layer 3 bonds to the solder layer 5 through the portion into which the Ni layer 4 diffuses. Further, the Ni—Co alloy layer 3 diffuses into the solder layer 5 consisting of the Sn—Ag alloy, whereby intermetallic compounds 7 containing an Ni—Sn alloy shown in FIG. 9 are formed in the solder layer 5. In addition, the Au layer 15 diffuses into the solder layer 5. Thus, the electronic component storage package according to the embodiment of the present invention is formed.

The electronic component storage package according to the embodiment of the present invention is constituted of the hermetic sealing cap 1, the electronic component 20 such as a SAW filter or a crystal oscillator and the electronic component storing member 10 for storing the electronic component 20. This electronic component storing member 10 includes the ceramic substrate 11 consisting of an insulating material such as alumina and the ceramic frame body 12 consisting of an insulating material such as alumina forming a storage space on a prescribed region of the surface of the ceramic substrate 11. The electronic component 20 is mounted on the portion of the ceramic substrate 11 located in the storage space enclosed with the ceramic frame body 12 through the bumps 21. The intermetallic compounds 7 are formed to have acicular shapes and diffuse into the whole of the solder layer 5. The portion of the Ni layer 4 formed with the solder layer 5 diffuses in the intermetallic compounds 7, and the Ni—Co alloy layer 3 bonds to the solder layer 5 through the portion in which the Ni layer 4 diffuses.

According to this embodiment, as hereinabove described, formation of the intermetallic compounds 7 in the solder layer 5 can be suppressed at the temperature (about 235° C.) for forming the solder layer 5 by making the Ni layer 4 function to inhibit the Ni—Co alloy layer 3 from diffusing into the solder layer 5 at the temperature (about 235° C.) for forming the solder layer 5, whereby the melting point of the solder layer 5 can be inhibited from increasing in the simple substance of the hermetic sealing cap 1. Thus, wettability of the solder layer 5 with respect to the electronic component storing member 10 can be inhibited from lowering when bonding the hermetic sealing cap 1 to the electronic component storing member 10 through the solder layer 5 by heating the same to the temperature (about 300° C. to about 320° C.) higher than the temperature (about 235° C.) for forming the solder layer 5, whereby airtightness of the electronic component storage package can be inhibited from lowering. Further, the solder layer 5 is so formed on the region of the surface of the Ni layer 4 to which the electronic component storing member 10 is bonded that the solder layer 5 can be inhibited from covering the upper surface of the electronic component 20 arranged in the electronic component storage package, whereby the solder layer 5 can be inhibited from spattering on the electronic component 20 when bonding the hermetic sealing cap 1 to the electronic component storing member 10. Thus, deterioration of the characteristics of the electronic component 20 can be suppressed. Further, the intermetallic compounds 7 can be formed in the solder layer 5 by making the Ni layer 4 function to diffuse the Ni—Co alloy layer 3 into the solder layer 5 when the solder layer 5 bonds to the electronic component storing member 10 at the temperature (about 300° C. to about 320° C.) higher than the temperature (about 235° C.) for forming the solder layer 5, whereby the melting point of the solder layer 5 after formation of the electronic component storage package can be increased. Thus, the solder layer 5 can be inhibited from melting resulting from such a situation that the electronic component storage package reaches a high temperature while the solder layer 5 also reaches a high temperature when mounting the electronic component storage package on a printed wiring board of an electronic apparatus. In this case, there is no need to employ high melting point solder consisting of a high-priced Au—Sn alloy or an Sn—Pb alloy, whereby the material cost can be reduced and solder containing no Pb can be used.

According to this embodiment, the Ni layer 4 is so arranged between the Ni—Co alloy layer 3 and the solder layer 5 that the Ni—Co alloy layer 3 can be easily inhibited from diffusing into the solder layer 5 through the Ni layer 4.

According to this embodiment, the Ni layer 4 is so formed in the thickness of at least 0.03 μm that the Ni layer 4 can be easily formed to have the function of inhibiting the Ni—Co alloy layer 3 from diffusing into the solder layer 5 at the temperature (about 235° C.) for forming the solder layer 5 while diffusing the Ni—Co alloy layer 3 into the solder layer 5 through the Ni layer 4 when the solder layer 5 bonds to the electronic component storing member 10 at the temperature (about 300° C. to about 320° C.) higher than the temperature (about 235° C.) for forming the solder layer 5.

According to this embodiment, the Ni—Co alloy layer 3 is made to contain 7.5 mass % to 20 mass % of Co as the diffusion accelerator so that the Ni—Co alloy layer 3 can be sufficiently diffused into the solder layer 5 through the Ni layer 4 when the solder layer 5 is bonded to the electronic component storing member 10 at the temperature (about 300° C. to about 320° C.) higher than the temperature (about 235° C.) for forming the solder layer 5, whereby sufficient quantities of intermetallic compounds 7 can be formed in the solder layer 5.

According to this embodiment, the low thermal expansion layer 2 is made of the Fe—Ni—Co alloy so that the thermal expansion coefficient of the low thermal expansion layer 2 can be reduced, whereby the thermal expansion coefficient of the hermetic sealing cap 1 can be reduced. Thus, thermal expansion coefficient difference between the hermetic sealing cap 1 and the electronic component storing member 20 can be reduced when the electronic component storing member 10 is made of a material such as ceramic having a small thermal expansion coefficient, whereby the junction between the hermetic sealing cap 1 and the electronic component storing member 10 can be inhibited from development of cracks and chaps under a high temperature.

According to this embodiment, the Ni—Co alloy layer 3 and the Ni layer 4 are so formed by plating that the Ni—Co alloy layer 3 and the Ni layer 4 can be easily formed.

According to this embodiment, the intermetallic compounds 7 increasing the melting point of the solder layer 6 are formed in bonding between the hermetic sealing cap 1 and the electronic component storing member 10 also when employing low melting point solder consisting of Sn—Ag containing no Pb for the solder layer 5, whereby the solder layer 5 can be inhibited from melting when mounting the electronic component storage package on a printed wiring board of an electronic apparatus or the like.

According to this embodiment, the solder layer 5 consisting of the Sn—Ag alloy is formed by arranging the solder paste 6 consisting of the Sn—Ag alloy on the region of the surface of the Ni layer 4 to which the electronic component storing member 10 is bonded and thereafter melting the solder paste 6 at the temperature of about 235° C., whereby the solder layer 5 consisting of the Sn—Ag alloy can be easily formed only on the region of the surface of the Ni layer 4 to which the electronic component storing member 10 is bonded.

### EXAMPLE

Comparative experiments performed for confirming the effects of the hermetic sealing cap 1 according to the aforementioned embodiment are now described. First, a comparative experiment for investigating growth (heat resistance of the solder layer 5) of the Ni—Sn alloy (intermetallic compounds 7) resulting from diffusion of the Ni—Co alloy layer 3 into the solder layer 5 consisting of the Sn—Ag alloy is described. In this comparative experiment, samples according to Examples 1 to 3 corresponding to this embodiment and samples according to comparative examples 1 to 3 were prepared.

First, low thermal expansion layers 2, consisting of an Fe—Ni—Co alloy, of about 3.5 mm square having thicknesses of about 0.15 mm were formed by punching a plate coil consisting of the Fe—Ni—Co alloy by press working. Ni—Co alloy layers 3 in which mass ratios of Co were set to 7.5 mass % (Example 1), 10 mass % (Example 2), 20 mass % (Example 3), 0 mass % (comparative example 1), 3 mass % (comparative example 2) and 5 mass % (comparative example 3) respectively were formed on the whole areas of the surfaces of these low thermal expansion layers 2 by plating with thicknesses of about 2 μm. Then, solder paste layers 6 consisting of an Sn—Ag alloy were formed on regions of the lower surfaces of the Ni—Co alloy layers 3 to which electronic component storing members 10 were bonded by screen printing with widths of about 0.45 mm and thicknesses of about 0.08 mm. The solder paste layers 6 were heated at a temperature (first temperature) of about 235° C. Growth states of Ni—Sn alloys (intermetallic compounds 7) were confirmed as to these samples. Table 1 shows the results.

TABLE 1

| | |
|---|---|
| | Growth of Ni—Sn Alloy |
| Content of Co (mass %) | (Intermetallic Compound) (Heat |
| in Ni—Co Alloy Layer | Resistance of Solder Layer) |

| | | |
|---|---|---|
| 0 | Comparative | x |
| | Example 1 | |
| 3 | Comparative | x |
| | Example 2 | |
| 5 | Comparative | x |
| | Example 3 | |
| 7.5 | Example 1 | ∘ |
| 10 | Example 2 | ∘ |
| 20 | Example 3 | ∘ |

Referring to the above Table 1, it has been proved that the intermetallic compounds 7 consisting of the Ni—Sn alloys sufficiently grow in the solder layers 5 consisting of the Sn—Ag alloy in the hermetic sealing caps 1 (Examples 1 to 3) employing the Ni—Co alloy layers 3 containing 7.5 mass % to 20 mass % of Co. On the other hand, it has been proved that the intermetallic compounds 7 consisting of the Ni—Sn alloys do not sufficiently grow in the solder layers 5 consisting of the Sn—Ag alloy in the hermetic sealing caps 1 (comparative examples 1 to 3) employing the Ni—Co alloy layers 3 containing 0 mass % to 5 mass % of Co. This is conceivably because the Ni—Co alloy layers 3 hardly diffuse into the solder layers 5 consisting of the Sn—Ag alloy as the contents of Co as diffusion accelerators in the Ni—Co alloy layers 3 decrease.

Another comparative experiment for investigating diffusion states of Ni—Co alloy layers 3 into solder layers 5 after formation of the solder layers 5 depending on the thicknesses of Ni layers 4 is now described. In this comparative experiment, samples according to Examples 4 to 6 corresponding to this embodiment and samples according to comparative examples 4 to 7 were prepared.

First, low thermal expansion layers 2, consisting of an Fe—Ni—Co alloy, of about 3.5 mm square having thicknesses of about 0.15 mm were formed by punching a plate coil consisting of the Fe—Ni—Co alloy by press working. Ni—Co alloy (Co: about 10 mass %) layers 3 were formed on the whole areas of the surfaces of these low thermal expansion layers 2 by plating with thicknesses of about 2 μl. Ni layers 4 having thicknesses of 0.03 μl (Example 4), 0.05 μm (Example 5), 0.075 μm (Example 6), 0 μm (comparative example 4), 0.01 μm (comparative example 5), 0.1 μm (comparative example 6) and 0.2 μm (comparative example 7) respectively were formed on the whole areas of the surfaces of the Ni—Co alloy layers 3 by plating.

Then, solder paste layers 6 consisting of an Sn—Ag alloy were formed on regions of the lower surfaces of the Ni layers 4 to which electronic component storing members 10 were bonded by screen printing with widths of about 0.45 mm and thicknesses of about 0.08 mm. The solder paste layers 6 were heated at a temperature (first temperature) of about 235° C. Diffusion states of the Ni—Co alloy layers 3 into the solder layers 5 consisting of the Sn—Ag alloy were confirmed as to these samples. Table 2 shows the results.

TABLE 2

| | |
|---|---|
| | Prevention of Diffusion of Ni—Co |
| Thickness of Ni Layer | Alloy Layer in Solder Layer after |
| (μm) | Formation of Solder Layer |

| | | |
|---|---|---|
| 0 | Comparative | x |
| | Example 4 | |
| 0.01 | Comparative | Δ |
| | Example 5 | |
| 0.03 | Example 4 | ∘ |
| 0.05 | Example 5 | ∘ |
| 0.075 | Example 6 | ∘ |
| 0.1 | Comparative | ∘ |
| | Example 6 | |
| 0.2 | Comparative | ∘ |
| | Example 7 | |

Referring to the above Table 2, it has been proved that the Ni layers 4 have functions of inhibiting the Ni—Co alloy layers 3 from diffusing into the solder layers 5 consisting of the Sn—Ag alloy in the hermetic sealing caps 1 (Examples 4 to 6 and comparative examples 6 and 7) employing the Ni layers 4 having the thicknesses of 0.03 μm to 0.2 μm.

Still another comparative experiment for investigating growth (diffusion of Ni layers 4 into solder layers 5) of Ni—Sn alloys (intermetallic compounds 7) after hermetic sealing depending on the thicknesses of Ni layers 4 is now described. In this comparative experiment, samples according to Examples 7 to 9 and comparative examples 8 to 11 were prepared by employing the aforementioned samples corresponding to Examples 4 to 6 and comparative examples 4 to 7 respectively. In this comparative experiment, an experiment on simple substances of hermetic sealing caps 1 was performed since growth (diffusion of Ni layers 4 into solder layers 5) of the Ni—Sn alloys (intermetallic compounds 7) resulting from diffusion of Ni—Co alloy layers 3 of hermetic sealing caps 1 into solder layers 5 becomes indefinite when Ni—Co alloy layers 14 of electronic component storing members 10 diffuse into the solder layers 5 consisting of an Sn—Ag alloy.

First, the electronic component storing members 10 obtained by forming tungsten layers 13, the Ni—Co alloy layers 14 and Au layers 15 on the upper surfaces of ceramic frame bodies 12 arranged on ceramic substrates 11 in this order were prepared. The samples according to Examples 7 to 9 and comparative examples 8 to 11 were prepared by melting the samples corresponding to Examples 4 to 6 and comparative examples 4 to 7 at a temperature (second temperature) of about 300° C. to about 320° C. Growth states of Ni—Sn alloys (intermetallic compounds 7) were confirmed as to these samples. Table 3 shows the results.

TABLE 3

| | |
|---|---|
| | Growth of Ni—Sn Alloy (Intermetallic |
| Thickness of Ni Layer | Compound) (Diffusion of Ni Layer in |
| (μm) | Solder Layer) after Hermetic Sealing |

| | | |
|---|---|---|
| 0 | Comparative | ∘ |
| | Example 8 | |
| 0.01 | Comparative | ∘ |
| | Example 9 | |
| 0.03 | Example 7 | ∘ |
| 0.05 | Example 8 | ∘ |
| 0.075 | Example 9 | ∘ |
| 0.1 | Comparative | Δ |
| | Example 10 | |
| 0.2 | Comparative | x |
| | Example 11 | |

Referring to the above Table 3, it has been proved that the Ni layers 4 diffuse into the solder layers 5 consisting of the Sn—Ag alloy while the Ni—Co alloy layers 3 diffuse into the solder layers 5 consisting of the Sn—Ag alloy through the portions into which the Ni layers 4 diffuse thereby forming the intermetallic compounds 7 in the hermetic sealing caps 1 (Examples 7 to 9 and comparative examples 8 and 9) employing the Ni layers 4 having the thicknesses of 0 μm to 0.075 μm.

The embodiments disclosed this time must be considered as illustrative and not restrictive in all points. The range of the present invention is shown not by the above description of the embodiments but the scope of claim for patent, and all modifications in the meaning and range equivalent to the scope of claim for patent are included.

For example, while the example of forming the Ni—Co alloy layer 3 on the whole areas of the surfaces of the low thermal expansion layer 2 by plating has been shown in the aforementioned embodiment, the present invention is not restricted to this but Ni—Co alloy layers 3a may be formed by pressure-welding the same to the upper surface and the lower surface of a low thermal expansion layer 2 as in a first modification according to the first embodiment of the present invention shown in FIG. 10, or an Ni—Co alloy layer 3b may be formed by pressure-welding the same to only the lower surface of a low thermal expansion layer 2 as in a second modification according to the embodiment of the present invention shown in FIG. 11.

While the example of setting the content of Co in the Ni—Co alloy layer 3 of the hermetic sealing cap to about 7.5 mass % to about 20 mass % has been shown in the aforementioned embodiment, the present invention is not restricted to this but the content of Co in the Ni—Co alloy layer 3 of the hermetic sealing cap may be set to less than 5 mass %. In this case, the content of Co in the Ni—Co alloy layer 14 of the electronic component storing member must be enlarged. Thus, the Ni—Sn alloy (intermetallic compounds) in the solder layer can be rendered easily growable by enlarging the content of Co in the Ni—Co alloy layer 14 of the electronic component storing member also when setting the content of Co in the Ni—Co alloy layer 3 of the hermetic sealing cap to less than 5 mass %, whereby the melting point of the solder layer can be increased. Thus, sufficient heat resistance can be attained when mounting the electronic component storage package on a printed wiring board of an electronic apparatus.

While the example of employing the Sn—Ag alloy (Ag: about 3.5 mass %) for the solder layer has been shown in the aforementioned embodiment, the present invention is not restricted to this but the content of Ag in the solder layer may be set to a content other than 3.5 mass %, or solder consisting of another composition mainly composed of Sn may be employed.

1. A hermetic sealing cap (1) employed for an electronic component storage package including an electronic component storing member (10) for storing an electronic component (20), comprising:
a substrate (2);
a first layer (3), formed on the surface of said substrate, mainly composed of Ni containing a diffusion accelerator;
a second layer (4) formed on the surface of said first layer; and
a solder layer (5) mainly composed of Sn formed on a region of the surface of said second layer to which said electronic component storing member is bonded, wherein
said second layer has a function of inhibiting said first layer from diffusing into said solder layer at a first temperature while diffusing said first layer into said solder layer through said second layer when said solder layer bonds to said electronic component storing member at a second temperature higher than said first temperature.

2. The hermetic sealing cap according to claim 1, wherein
said first temperature is a temperature at a time of forming said solder layer by melting solder paste (6), and
said second temperature is a temperature at a time of bonding said hermetic sealing cap to said electronic component storing member by melting said solder layer.

3. The hermetic sealing cap according to claim 1, wherein
said second layer is made of Ni.

4. The hermetic sealing cap according to claim 3, wherein
said second layer has a thickness of at least 0.03 μm and not more than 0.075 μm.

5. The hermetic sealing cap according to claim 1, wherein
said first layer contains 7.5 mass % to 20 mass % of Co as said diffusion accelerator.

6. The hermetic sealing cap according to claim 1, wherein
said substrate is made of an Fe—Ni—Co alloy.

7. The hermetic sealing cap according to claim 1, wherein
said first layer and said second layer are formed by plating.

8. The hermetic sealing cap according to claim 7, wherein
said first layer is formed on the whole area of the surface of said substrate, and
said second layer is formed on the whole area of the surface of said first layer.

9. The hermetic sealing cap according to claim 1, wherein
said solder layer contains no Pb, and contains Ag.

10. An electronic component storage package including an electronic component storing member (10) for storing an electronic component (20), comprising:
a hermetic sealing cap (1) including a substrate (2), a first layer (3), formed on the surface of said substrate, mainly composed of Ni containing a diffusion accelerator, a second layer (4) formed on the surface of said first layer and a solder layer (5) mainly composed of Sn formed on a region of the surface of said second layer to which said electronic component storing member is bonded, with said second layer having a function of inhibiting said first layer from diffusing into said solder layer at a first temperature while diffusing said first layer into said solder layer through said second layer when said solder layer bonds to said electronic component storing member at a second temperature higher than said first temperature, wherein
a third layer (14) is formed on a portion of said electronic component storing member corresponding to said solder layer,
said solder layer and said third layer are bonded to each other, and
an intermetallic compound (7) containing Sn of said solder layer is formed on the junction between said hermetic sealing cap and said electronic component storing member.

11. The electronic component storage package according to claim 10, wherein
the junction between said hermetic sealing cap and said electronic component storing member contains an intermetallic compound consisting of an Ni—Sn alloy, and
a portion of said second layer corresponding to the junction between said hermetic sealing cap and said electronic component storing member diffuses in said intermetallic compound.

12. A method of manufacturing a hermetic sealing cap (1) employed for an electronic component storage package including an electronic component storing member (10) for storing an electronic component, comprising steps of:
preparing a substrate (2);
forming a first layer (3) mainly composed of Ni containing a diffusion accelerator on the surface of said substrate;
forming a second layer (4) on the surface of said first layer; and
forming a solder layer (5) mainly composed of Sn on a region of the surface of said second layer to which said electronic component storing member is bonded, wherein
the step of forming said second layer includes a step of forming the second layer having a function of inhibiting said first layer from diffusing into said solder layer when forming said solder layer at a first temperature while diffusing said first layer into said solder layer through said second layer when said solder layer bonds to said electronic component storing member at a second temperature higher than said first temperature.

13. The method of manufacturing a hermetic sealing cap according to claim 12, wherein
the step of forming said solder layer includes steps of arranging solder paste (6) mainly composed of Sn on a region of the surface of said second layer to which said electronic component storing member is bonded and forming said solder layer mainly composed of said Sn by melting said solder paste at said first temperature.

14. The method of manufacturing a hermetic sealing cap according to claim 12, wherein
said second layer is made of Ni.

15. The method of manufacturing a hermetic sealing cap according to claim 14, wherein
said second layer has a thickness of at least 0.03 μm and not more than 0.075 μm.

16. The method of manufacturing a hermetic sealing cap according to claim 12, wherein
said first layer contains 7.5 mass % to 20 mass % of Co as said diffusion accelerator.

17. The method of manufacturing a hermetic sealing cap according to claim 12, wherein
said substrate is made of an Fe—Ni—Co alloy.

18. The method of manufacturing a hermetic sealing cap according to claim 12, wherein
the step of forming said first layer includes a step of forming said first layer by plating, and
the step of forming said second layer includes a step of forming said second layer by plating.

19. The method of manufacturing a hermetic sealing cap according to claim 18, wherein
the step of forming said first layer by plating includes a step of forming said first layer on the whole area of the surface of said substrate, and
the step of forming said second layer by plating includes a step of forming said second layer on the whole area of the surface of said first layer.

20. The method of manufacturing a hermetic sealing cap according to claim 12, wherein
said solder layer contains no Pb, and contains Ag.
